(19) United States
(12) Patent Application Publication
(10) Pub. No.: US 2023/0280977 A1
(43) Pub. Date: Sep. 7, 2023

(54) ARITHMETIC PROCESSING APPARATUS AND METHOD FOR MEMORY ACCESS

(71) Applicants: Fujitsu Limited, Kawasaki-shi (JP); KEIO UNIVERSITY, Tokyo (JP)

(72) Inventors: Masaaki Kondo, Yokohama (JP); Makiko Ito, Kawasaki (JP)

(73) Assignees: Fujitsu Limited, Kawasaki-shi (JP); KEIO UNIVERSITY, Tokyo (JP)

(21) Appl. No.: 18/103,654

(22) Filed: Jan. 31, 2023

(30) Foreign Application Priority Data
Mar. 2, 2022 (JP) 2022-031938

(51) Int. Cl. G06F 7/556; G06F 7/57

(52) U.S. Cl. CPC G06F 7/556; G06F 7/57

(57) ABSTRACT

An arithmetic processing apparatus includes a controlling unit that refers to an attribute of a compressing scheme on data on a main memory when the data is transferred between the main memory and a memory controller, and that transfers the data by switching the compressing scheme based on the referred attribute.

### CROSS-REFERENCE TO RELATED APPLICATION

This application is based upon and claims the benefit of priority of the prior Japanese Patent application No. 2022-031938, filed on Mar. 2, 2022, the entire contents of which are incorporated herein by reference.

### FIELD

The embodiment discussed herein relates to an arithmetic processing apparatus and a method for memory access.

### BACKGROUND

In scientific computation such as physical simulation, simultaneous linear equations for large-scale sparse matrices are solved. Scientific computation uses the cyber-physical system (CPS) and the critical data infrastructure for big data processing that supports the Society 5.0, which is a Japanese scientific and technological agenda, and the large-scale graphical data architecture.
[Patent Document 11 Japanese Laid-open Patent Publication No. 2019-208203
[Patent Document 2] Japanese National Publication of International Patent Application No. 2017-516232
[Patent Document 3] US Patent Application Publication No. 2020/0201602
[Patent Document 4] U.S. Pat. No. 10,122,379

The graph analysis process used in the scientific computation is basically a sparse matrix arithmetic operation in many cases. Although an architecture capable of efficiently handling these sparse matrix arithmetic operations has been studied, a memory bandwidth may come to be a bottleneck in a sparse matrix arithmetic operation as compared with the arithmetic processing in a core.

### SUMMARY

As an aspect, an arithmetic processing apparatus includes a controlling unit that refers to an attribute of a compressing scheme on data on a main memory when the data is transferred between the main memory and a memory controller, and that transfers the data by switching the compressing scheme based on the referred attribute.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating data transfer in a multi-core processor according to a related example;

FIG. 2 is a block diagram illustrating data transfer of compressed data in a multi-core processor of a related example;

FIG. 3 is a block diagram illustrating data transfer switching between compressed data and uncompressed data in a multi-core processor of a related example;

FIG. 4 is a block diagram illustrating data transfer in a multi-core processor according to an embodiment;

FIG. 5 is a table illustrating an example of a TLB and compression information of FIG. 4;

FIG. 6 is a diagram illustrating an example of an SpMV arithmetic operation of data compression on a bus in the embodiment;

FIG. 7 is a diagram illustrating a pseudo code of the SpMV arithmetic operation illustrated in FIG. 6;

FIG. 8 is a diagram illustrating a compressing process in data transfer of the embodiment;

FIG. 9 is a diagram illustrating a changing process of a compressing scheme on the basis of a threshold of the embodiment;

FIG. 10 is a table illustrating an example of a TLB and compression information of FIG. 9;

FIG. 11 is a diagram illustrating a lossless compressing process according to a first modification;

FIG. 12 is a diagram illustrating a case where transfer data is incompressible in the first modification;

FIG. 13 is a block diagram illustrating an example of a multi-core processor of the first modification;

FIG. 14 is a table illustrating an example of a TLB and compression information of the first modification;

FIG. 15 is a diagram illustrating a first example of evaluating a compressing ratio in the first modification;

FIG. 16 is a diagram illustrating a second example of evaluating a compressing ratio in the first modification;

FIG. 17 is a diagram illustrating a first example of a compressing process of a second modification;

FIG. 18 is a diagram illustrating a second example of a compressing process of the second modification;

FIG. 19 is a diagram illustrating a first example of evaluating a compressing ratio in the second modification;

FIG. 20 is a diagram illustrating a second example of evaluating a compressing ratio in the second modification;

FIG. 21 is a diagram illustrating a third example of evaluating a compressing ratio in the second modification;

FIG. 22 is a diagram illustrating a fourth example of evaluating a compressing ratio in the second modification;

FIG. 23 is a diagram illustrating a fifth example of evaluating a compressing ratio in the second modification;

FIG. 24 is a table illustrating an example of a TLB in a case of a combination of the embodiment, the first modification, and the second modification;

FIG. 25 is a block diagram schematically illustrating an example of a hardware configuration of a multi-core processor of the embodiment;

FIG. 26 is a flow diagram illustrating a data transferring process in a transfer IF of a memory controller of the embodiment;

FIG. 27 is a flow diagram illustrating a data transferring process in a transfer IF of a main memory of the embodiment;

FIG. 28 is a flow diagram illustrating a selecting process of a compressing scheme of the embodiment;

FIG. 29 is a flow diagram illustrating a selecting process of a compressing scheme of the first and second modifications;

FIG. 30 is a flow diagram illustrating a selecting process of a compressing scheme of the embodiment, the first and second modifications;

FIG. 31 is a diagram illustrating an updating process of statistic information when data transmitting and receiving in the embodiment;

FIG. 32 is a diagram illustrating an updating process of statistic information when bit width adjustment in the embodiment;

FIG. 33 is a flow diagram illustrating a data compressing process of the embodiment;

FIG. 34 is a flow diagram illustrating a data decompressing process of the embodiment;

FIG. 35 is a flow diagram illustrating a data compressing process of the first modification;

FIG. 36 is a flow diagram illustrating a data decompressing process of the first modification;

FIG. 37 is a flow diagram illustrating a first example of a data compressing process of the second modification;

FIG. 38 is a flow diagram illustrating a first example of a data decompressing process of the second modification;

FIG. 39 is a flow diagram illustrating a second example of a data compressing process of the second modification;

FIG. 40 is a flow diagram illustrating a second example of a data decompressing process of the second modification; and

FIG. 41 is a table illustrating performance of SpMV calculation by data compression of the embodiment, the first embodiment, and the second embodiment.

### DESCRIPTION OF EMBODIMENT(S)

### (A) Related Examples

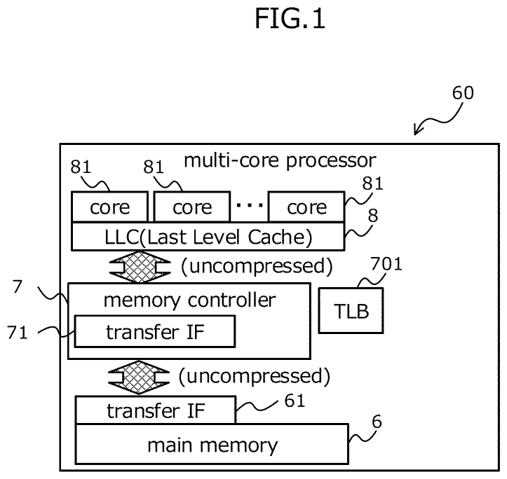

FIG. 1 is a block diagram illustrating data transfer in a multi-core processor 60 according to a related example.

A multi-core processor 60 includes a main memory 6, a memory controller 7, an LLC (Last Level Cache) 8, and multiple cores 81. In addition, the multi-core processor 60 retains a TLB (Translation Lookaside Buffer) 701.

The main memory 6 includes a transfer IF (Interface) 61 and transfers data to the memory controller 7 without compressing the data.

The memory controller 7 includes a transfer IF 71 and transfers data that the main memory 6 receives to the LLC 8 without compressing the data. The memory controller 7 uses information of the TLB 701 that the multi-core processor 60 retains.

The multiple cores 81 process data received from the memory controller 7 via the LLC 8. On the side of the multiple cores 81, address translation may be performed by obtaining attribute information with reference to the TLB 701, using a physical address.

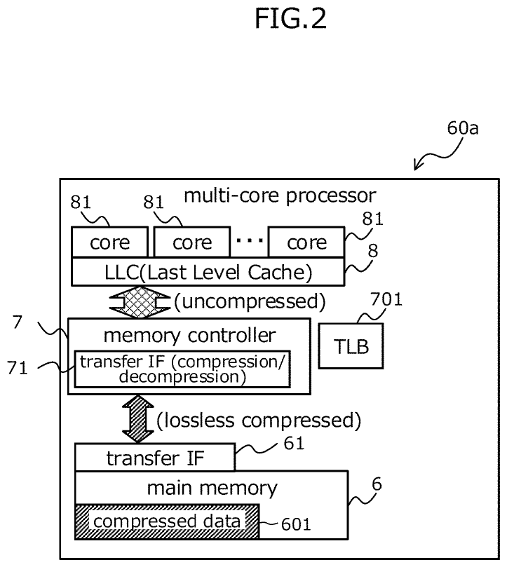

FIG. 2 is a block diagram illustrating data transfer of compressed data in the multi-core processor 60 of the related example.

In the multi-core processor 60a illustrated in FIG. 2, compressed data 601 is arranged in the main memory 6 as compared with the multi-core processor 60 illustrated in FIG. 1.

The transfer IF 61 of the main memory 6 transfers the compressed data 601 to the memory controller 7 in a lossless compressing scheme.

The transfer IF 71 of the memory controller 7 transfers the compressed data 601 received from the main memory 6 to the LLC 8 in a uncompressing scheme.

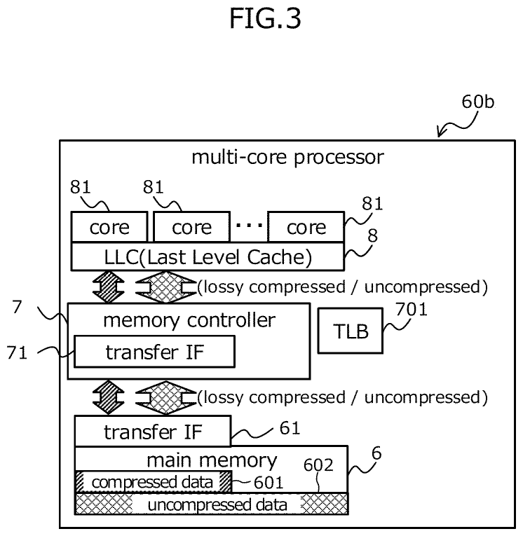

FIG. 3 is a block diagram illustrating data transfer switching between compressed data and uncompressed data in the multi-core processor 60a of the related example.

In the multi-core processor 60b illustrated in FIG. 3, compressed data 601 and uncompressed data 602 are arranged in the main memory 6 as compared with the multi-core processor 60 illustrated in FIG. 1.

The transfer IF 61 of the main memory 6 transfers the lossy compressed data 601 to the memory controller 7 in a lossy compressing scheme and transfers the uncompressed data 602 to the memory controller 7 in an uncompressing scheme.

The transfer IF 71 of the memory controller 7 transfers the lossy compressed data 601 to the LLC 8 in a lossy compressing scheme, and transfers the uncompressed data 602 received from the main memory 6 to the LLC 8 in an uncompressing scheme.

The multi-core processor 60b illustrated in FIG. 3 performs computation while stepwisely switching between compression and uncompression of data from the software in a CPU (Central Processing Unit). However, this manner needs to place both the compressed data 601 and the uncompressed data 602 in the main memory 6, and therefore switching between the compression and uncompression has a possibility of not being achieved due to lack of the memory capacity.

### [B] Embodiment

Hereinafter, an embodiment will now be described with reference to the accompanying drawings. However, the following embodiment is merely illustrative and is not intended to exclude the application of various modifications and techniques not explicitly described in the embodiment. Namely, the present embodiment can be variously modified and implemented without departing from the scope thereof. Further, each of the drawings can include additional functions not illustrated therein to the elements illustrated in the drawing.

Hereinafter, like reference numbers designate the same or similar elements, so repetitious description is omitted here.

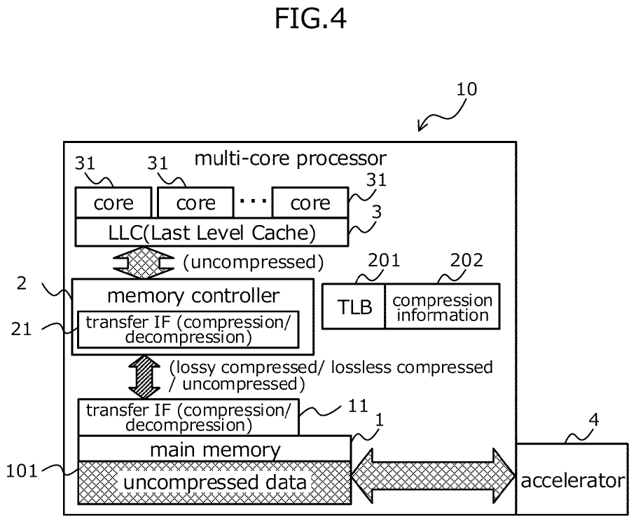

FIG. 4 is a block diagram illustrating data transfer in a multi-core processor 10 according to the embodiment.

The multi-core processor 10 includes a main memory 1 (in other words, a main storing device), a memory controller 2, an LLC 3, and multiple cores 31. The multi-core processor 10 further retains a TLB 201 and compression information 202.

The main memory 1 includes a transfer IF 11 serving as an example of a controlling unit, and transfers uncompressed data 101 to the memory controller 2 in a lossy compressing scheme, a lossless compressing scheme, or an uncompressing scheme.

The memory controller 2 includes a transfer IF 21 serving as an example of the controlling unit, and transfers the uncompressed data 101 that the main memory 1 receives to the LLC 3 without compressing the data. In addition, the memory controller 2 uses the TLB 201 and compression information 202 held by the multi-core processor 10. The memory controller 2 compresses and decompresses the data.

The multiple cores 31 process data received from the memory controller 2 via the LLC 3. On the side of the multiple cores 31, address translation may be performed by obtaining attribute information with reference to the TLB 201, using a physical address.

The multi-core processor 10 transfers data between the main memory 1 and the LLC 3 with or without compressing the data. The design of the LLC 3 and the cores 31 need not to be changed from that of the related examples illustrated in FIGS. 1 to 3. Since a compressed access is designated as an attribute of a page table, the compressing ratio is improved by lossy compression with loss that can be set by software (System call). By accumulating information at the time of compressing and adjusting the compressing ratio in cooperation with an application, the influence on the precision in the arithmetic operation can be reduced.

In addition, lossy compression can largely heighten the compressing ratio. Being retained in the form of the uncompressed data 101 on the main memory 1, the data can be easily shared by another device such as an accelerator 4. In the related examples, fragmentation may occur when the written data is compressed. In contrast, in the embodiment, since fragmentation does not occur, memory control can be efficiently performed.

Furthermore, in the embodiment, since the compressing scheme is switched at the time of transfer, it is sufficient that only a region for uncompressed data needs to be reserved in the main memory 1, so that the switching can be facilitated.

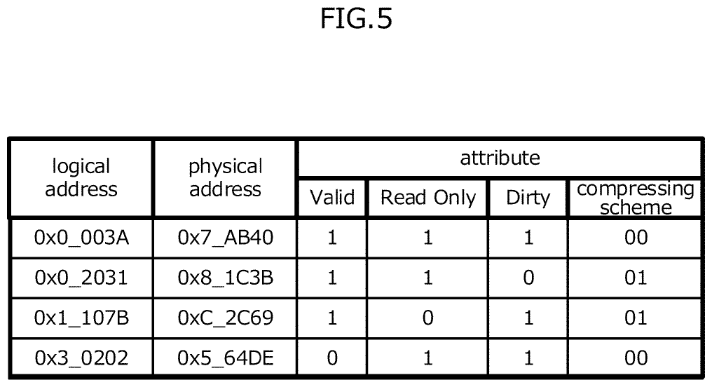

FIG. 5 is a table illustrating examples of the TLB 201 and the compression information 202 illustrated in FIG. 4.

In the TLB 201 and the compression information 202, a logical address, a physical address, and attributes are associated with one another. The attributes may include “Valid”, “Read Only”, “Dirty”, and a compressing scheme. In the attributes of “Valid”, “Read Only” and “Dirty”, the value “1” indicates valid, and the value “0” indicates invalid. In the attribute of “compressing scheme”, the value “00” may indicate lossy compression, and the value “01” may indicate lossless compression.

That is, the transfer IF 21 refers to the attribute of the compressing scheme for the data on the main memory 1 when data transfer between the main memory 1 and the memory controller 2. The transfer IF 21 switches a compressing scheme based on the referred attribute and performs data transfer in the switched compressing scheme.

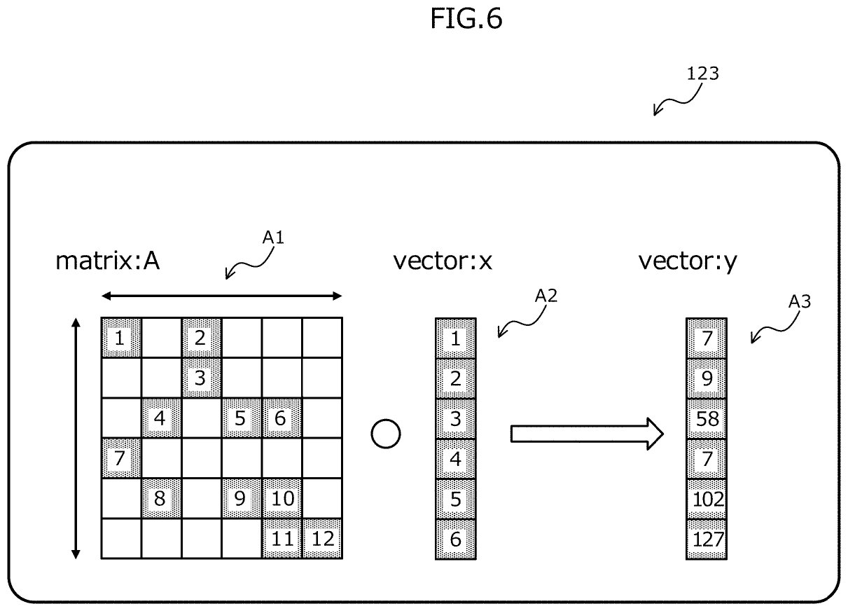

FIG. 6 is a diagram illustrating an example of an SpMV arithmetic operation in the data compression on a bus in the embodiment.

The SpMV arithmetic operation illustrated in FIG. 6 obtains the vector y represented by the reference sign A3 by the product of the sparse matrix A represented by the reference sign A1 and the vector x represented by the reference sign A2.

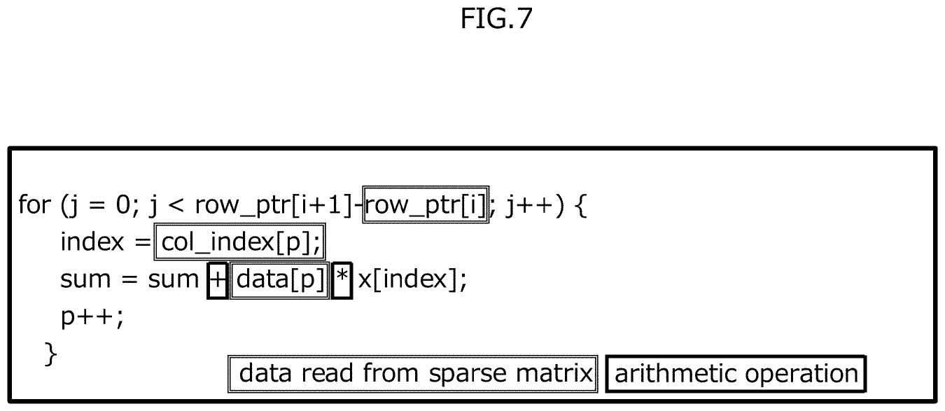

FIG. 7 is a diagram illustrating a pseudo code of the SpMV arithmetic operation illustrated in FIG. 6.

In the pseudo code illustrated in FIG. 7, the double frame indicates data read from the sparse matrix, and the dashed frame indicates an arithmetic operation.

Here, the B/F ratio of an SpMV will now be examined. A B/F ratio is a memory band width required for each individual arithmetic operation.

The data read from the matrix is represented by 12B+α(8 B(data)+4 B (col_index)+α(row_ptr)), and the arithmetic operation is represented by 2FLOP (+, *). The B/F rate requested by the SpMV is (12 B+α)/2FLOP=6B/F. Assuming that the memory band width (upper limit of hardware) of A64FX is 0.4 Byte/Flop, the execution performance of the SpMV is 0.4/6=6.7%. That is, 93.3% of execution time is time for waiting for data supply from the memory.

By compressing the sparse matrix data as the above, the B/F ratio of the SpMV can be reduced and accordingly, the execution performance can be improved.

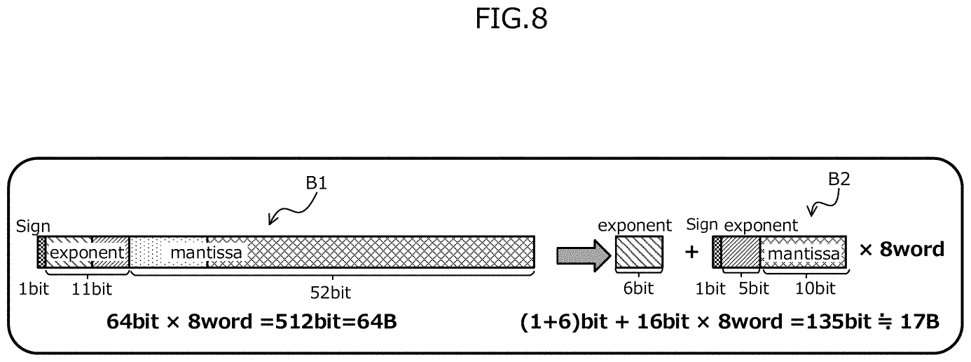

FIG. 8 is a diagram illustrating a compressing process in data transfer of the embodiment.

In the compressing process according to the embodiment, the conversion from double precision floating-point number to a single-precision floating-point number is performed, data is compressed, and the conversion from double precision to half precision is performed.

In the conversion to a single-precision floating-point number, DP (double-precision floating-point) data is lossly converted to SP (single-precision floating-point) data and the SP data is transferred.

In the compression of col_index, which is integer data, compression is performed on the upper bits common to the cache line and the lower bits of each word. Since neighboring col_indices have relatively close values, the upper bits are often common. Also, in the compression of col_index, each line is determined whether to be a compressed line simply by referring to the first bit of the line. If the line is incompressible, line transfer is performed with the normal bit number.

In the conversion from the double-precision or the single-precision to the half-precision, if the upper bits of the exponent are common, the compression is performed in a unit of a cache line.

In the example illustrated in FIG. 8, as indicated by the reference sign B1, data composed of a one-bit sign, an 11-bit exponent, and a 52-bit mantissa is given. The data represented by the reference sign B1 has a size of 64 bits×8 words=512 bits=64 Bytes.

As illustrated in the reference sign B2, the compressed data is obtained by compressing the configuration of the six-bits exponent and the configuration of the one-bit sign, the five-bit exponent, and the ten-bit mantissa into eight-word data. The data represented by the reference sign B2 has a size of (1+6) bits+16 bits×8 words=135 bits≈17 Bytes.

Here, description will now be made in relation to a procedure of solving a simultaneous linear equation b=A x by an iterative method using lossy compression.

First, a matrix A and a vector b are given.

As the initialization process, the following (eq. 1) and (eq. 2) are calculated.

p⁽⁰⁾=r⁽⁰⁾=b−A (eq. 1)

norm=∥r⁽⁰⁾∥ (eq. 2)

k=0

The calculation of following (eq. 3) to (eq. 9) are repeated until norm<ε.

$${α}_{k} = \frac{( {p}^{( k )} , {r}^{( k )} )}{( {p}^{( k )} , {Ap}^{( k )} )} ( where A p ( k ) is an SpMV ) \qquad ( eq . 3 )$$

$${β}_{k} = \frac{( {r}^{( k + 1 )} , {r}^{( k + 1 )} )}{( {r}^{( k )} , {r}^{( k )} )} \qquad ( eq . 4 )$$

$${p}^{( k + 1 )} = {r}^{( k + 1 )} + {β}_{k} \qquad ( eq . 5 )$$

$${x}^{( k + 1 )} = {x}^{( k )} + {α}_{k} \qquad ( eq . 6 )$$

$${r}^{( k + 1 )} = {r}^{( k )} - {α}_{k} A \qquad ( eq . 7 )$$

$$norm = ‖ {r}^{( k + 1 )} ‖ \qquad ( eq . 8 )$$

$$k += 1 \qquad ( eq . 9 )$$

Next, description will now be made in relation to changing a compressing scheme in the middle of the repeating.

First, a matrix A and a vector b are given.

As the initialization process, the following (eq. 10) and (eq. 11) are calculated.

p⁽⁰⁾=r⁽⁰⁾=b−A (eq. 10)

norm=∥r⁽⁰⁾∥ (eq. 11)

Compressing scheme=lossy compression (SP) is specified, and then the calculation of following (eq. 12) to (eq. 18) are repeated until norm<ε.

$${α}_{k} = \frac{( {p}^{( k )} , {r}^{( k )} )}{( {p}^{( k )} , {Ap}^{( k )} )} ( where A p ( k ) is an SpMV ) \qquad ( eq . 12 )$$

$${β}_{k} = \frac{( {r}^{( k + 1 )} , {r}^{( k + 1 )} )}{( {r}^{( k )} , {r}^{( k )} )} \qquad ( eq . 13 )$$

$${p}^{( k + 1 )} = {r}^{( k + 1 )} + {β}_{k} \qquad ( eq . 14 )$$

$${x}^{( k + 1 )} = {x}^{( k )} + {α}_{k} \qquad ( eq . 15 )$$

$${r}^{( k + 1 )} = {r}^{( k )} - {α}_{k} A \qquad ( eq . 16 )$$

$$norm = ‖ {r}^{( k + 1 )} ‖ \qquad ( eq . 17 )$$

When norm<α (threshold) is established, the compressing scheme is changed to compressing scheme=uncompressing.

k+=1 (eq. 18)

The calculation is finally executed with the DP, and since the arithmetic operation is repeated until the error comes to be within the specified error ε, the precision falls within the requested range when the arithmetic operation converges. By using lossy compression (SP), the performance of the SpMV can be improved, and switching on the main memory 1, which is in the DP, is facilitated.

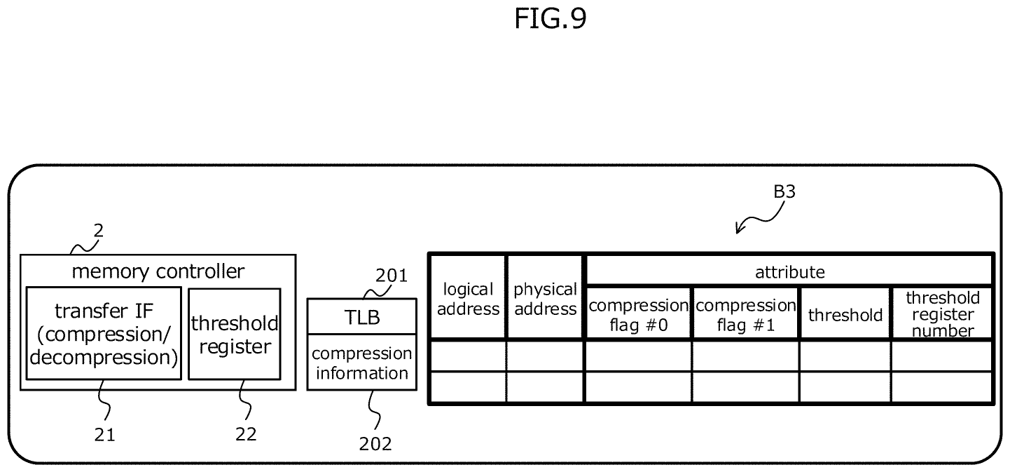

FIG. 9 is a diagram illustrating a switching process of a compressing scheme on the basis of a threshold of the embodiment.

As illustrated in FIG. 9, the memory controller 2 may include a threshold register 22 in addition to the transfer IF 21. Although a single threshold register 22 appears in FIG. 9. Alternatively, multiple threshold registers 22 may be provided.

When norm<α (threshold) is established, the compressing scheme is changed to compressing scheme=uncompressing.

The change of a compressing scheme may be achieved by means of software through changing the attribute of the page table in the tables of the TLB and the compression information illustrated in the reference sign B3. When norm<α (threshold) is established, the compression flag of the attribute may be changed to the uncompressing by a system call.

In the tables of the TLB and the compression information represented by the reference sign B3, a logical address, a physical address, and attributes are associated with one another. The attributes may include a compression flag #0, a compression flag #1, a threshold, and a threshold register number.

Further, the switching of the compressing scheme may be achieved by changing a value of the dedicated threshold register 22 in the memory controller 2. The value (norm) of the threshold register 22 is updated from the software.

Additionally, as illustrated by the reference sign B3, multiple compression flags #0 and #1 and a threshold are added to the attributes of the page table. If the value of the threshold register 22 is less than the specified threshold, compression or decompression is performed on the basis of the value of the compression flag #0. If the value of the threshold register 22 is equal to or larger than the specified threshold, compression or decompression is performed on the basis of the value of the compression flag #1.

This means that the transfer IF 21 switches the compressing scheme on the basis of the result of comparison of the predetermined threshold with the value of the threshold register 22 provided in the memory controller 2.

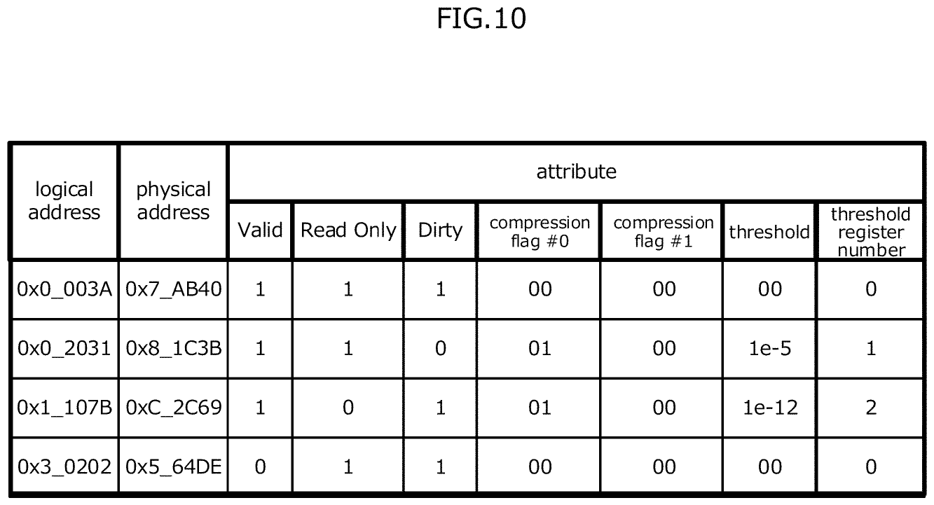

FIG. 10 is a table illustrating examples of a TLB and the compression information of FIG. 9.

In the tables of the TLB and the compression information, a logical address, a physical addresses, and attributes are associated with one another. The attributes may include “Valid”, “Read Only”, “Dirty”, “compression flag #0”, “compression flag #1”, a threshold, and a threshold register number. In the attributes of “Valid”, “Read Only” and “Dirty”, the value “1” indicates valid, and the value “0” indicates invalid. In the attributes of “compressing scheme”, the value “00” may indicate lossy compression, and the value “01” may indicate lossless compression. The threshold register number is a number for identifying the corresponding threshold register 22 among the multiple threshold registers 22 provided to the memory controller 2.

Here, description will now be made in relation to a method of solving a simultaneous linear equation b=A x by an iterative method.

First, a matrix A and a vector b are given, and an initialization process is performed. Then, the following processes (1) to (3) are repeated.
(1) In x^{k+1}=f(A, b, x^{k}), a solution x^{k+1} closer to the correct solution is calculated.
(2) When g(x^{k+1})<ε (tolerance error range) is satisfied, the solution ends.
(3) k+=1.

Next, description will now be made in relation to a method of changing the compressing scheme in the middle of the repeating.

First, a matrix A and a vector b are given, x⁰ is initialized, and k=0 is given. The compressing scheme=compressing scheme #3 is specified and an initialization process is performed. Then, the following processes (1) to (4) are repeated.
(1) In x^{k+1}=f(A, b, x^{k}), a solution x^{k+1} closer to the correct solution is obtained.
(2) When g(x^{k+1})<ε (tolerance error range) is satisfied, the solution ends.
(3) When g(x^{k+1})<αₓ is satisfied, the compressing scheme is changed to a compressing scheme #x.
(4) k+=1

(B-1) First Modification:

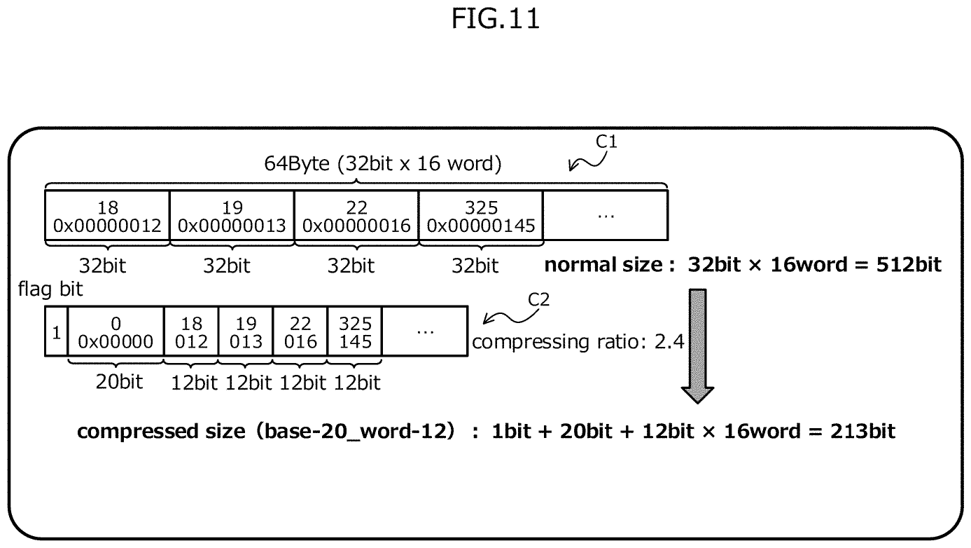

FIG. 11 is a diagram illustrating a lossless compressing process according to a first modification.

In the first modification, the colidx compression is carried out by a lossless compression scheme. Compression is performed on the upper bits common to the cache lines and the lower bits of each word. Since neighboring colidxes have relatively close values, the upper bits are often common. Each line is determined whether to be a compressed line simply by referring to the first bit of the line. If the line is incompressible, line transfer is performed with the normal bit number.

In the example represented by a reference sign C1, the line size is 64B which is derived by colidx[ ]=[18, 19, 22, 325, 343, . . . ] in the normal data prior to being compressed. That is, the size of the normal data is 32 bits×16 words=512 bits.

In the example represented by the reference sign C2, the compressed data is formed of a one-bit flag bit (“1” indicating compressed data), a 20-bit base bit, and 12-bits word. That is, the size of the compressed data is 1 bit+20 bits+12 bits×16 words=13 bits and the compressing ratio is 2.4.

That is, the transfer IF 21 divides each of the cache lines of data into an upper part having a predetermined bit number and a lower part. If the upper parts of the cache lines are common, the transfer IF 21 performs data transfer of the common upper part and the lower parts of the respective data words.

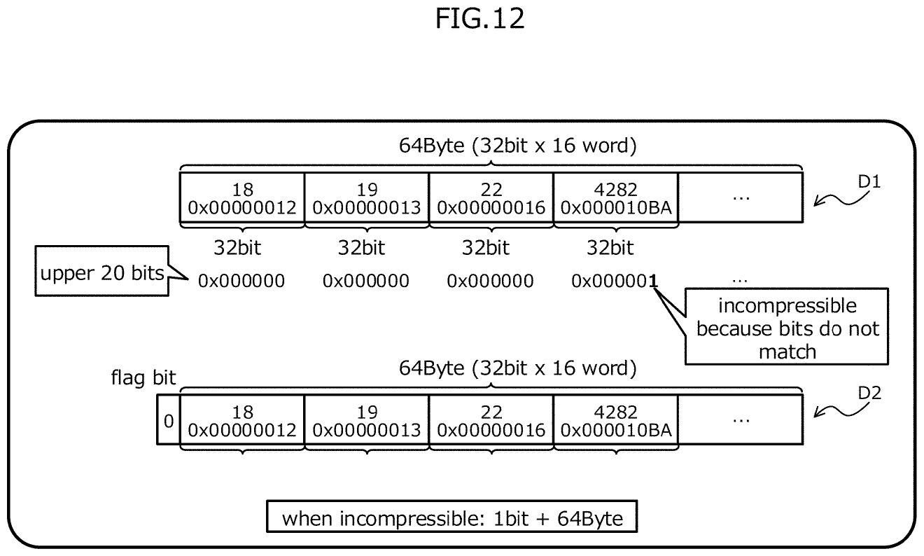

FIG. 12 is a diagram illustrating a case where the transfer data is incompressible in the first modification.

In the example represented by the reference sign D1, the upper 20 bits of the each word of the data of 32 bits×16 words=64 Byte are referred to. If at least one of the 20 upper bits in the respective words do not match, the data is determined to be incompressible.

In the example illustrated in the reference sign D2, a one-bit flag bit (“0” indicating uncompressed data) is attached to the leading position of the original data indicated by the reference signal D1 to indicate incompressible data. That is, the data size of incompressible data is 1 bit+64 Bytes.

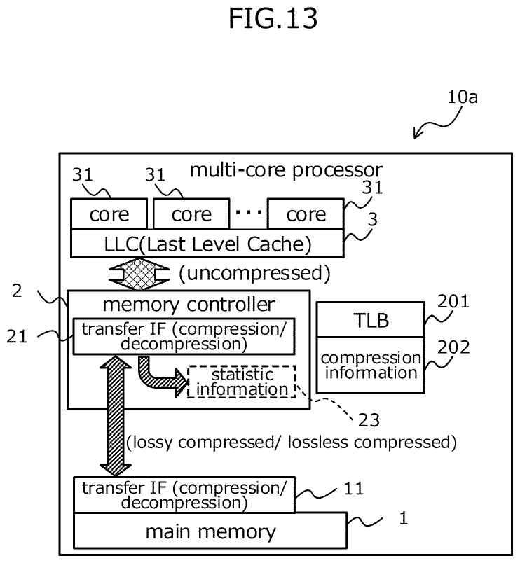

FIG. 13 is a diagram illustrating a multi-core processor 10a according to the first modification.

In the multi-core processor 10a according to the first modification illustrated in FIG. 13, the memory controller 2 may additionally retains statistic information 23 as compared with the multi-core processor 10 of the embodiment illustrated in FIG. 4. Note that when the common bit number is fixed, the statistic information 23 may be omitted because adjustment of the bit number is not required.

When transfer, an access count per page and success/failure in the compression are counted. For example, the page size may be four KB and the cache line size may be 64 B.

An adjusting process of the common bit number may be carried out periodically (e.g., when the access count reaches a predetermined value). If the success ratio lowers, the bit number may be increased, and if the success ratio is high, the bit number may be decreased.

If the compressed data is read-only data, adjustment may be made, before the start of an adjusting process of a bit width, such that the compressed success ration comes to be equal to or higher than a predetermined value. In this case, the common bit number is set to be small, so that data reading is repeated, and the common bit number is increased when the success ratio is less than or equal to or less than the predetermined value.

That is, the transfer IF 21 changes the bit number of the upper part according to the success ratio of data compressing.

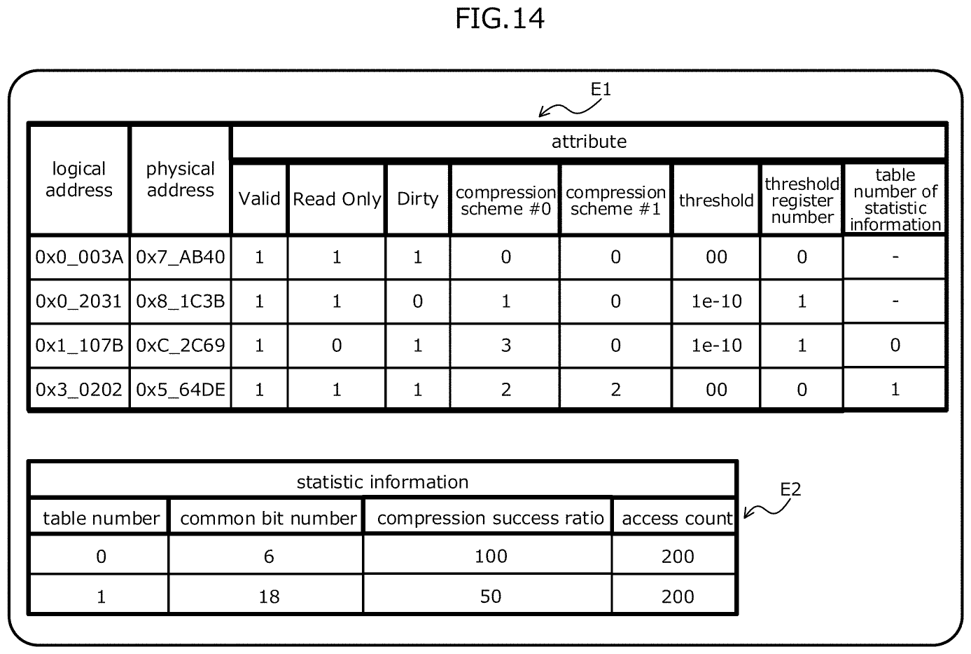

FIG. 14 is a table illustrating the TLB 201 and the statistic information 23 in the first modification.

In the TLB 201 represented by the reference sign E1, a logical address, a physical address, and attributes are associated with one another. The attributes may include “Valid”, “Read Only”, “Dirty”, compressing scheme #0, compressing scheme #1, a threshold, a threshold register number, and a statistic information table number.

For the data of the logical address 0x1_107B represented by the reference sign E1, the statistic information table number is set to “0”, which means that the data corresponds to data of the table number “0” of the statistic information 23 represented by the reference sign E2. In addition, for the data of the logical address 0x3_0202 represented by the reference sign E1, the statistic information table number is set to “1”, which means that the data corresponds to data of the table number “1” of the statistic information 23 represented by the reference sign E2.

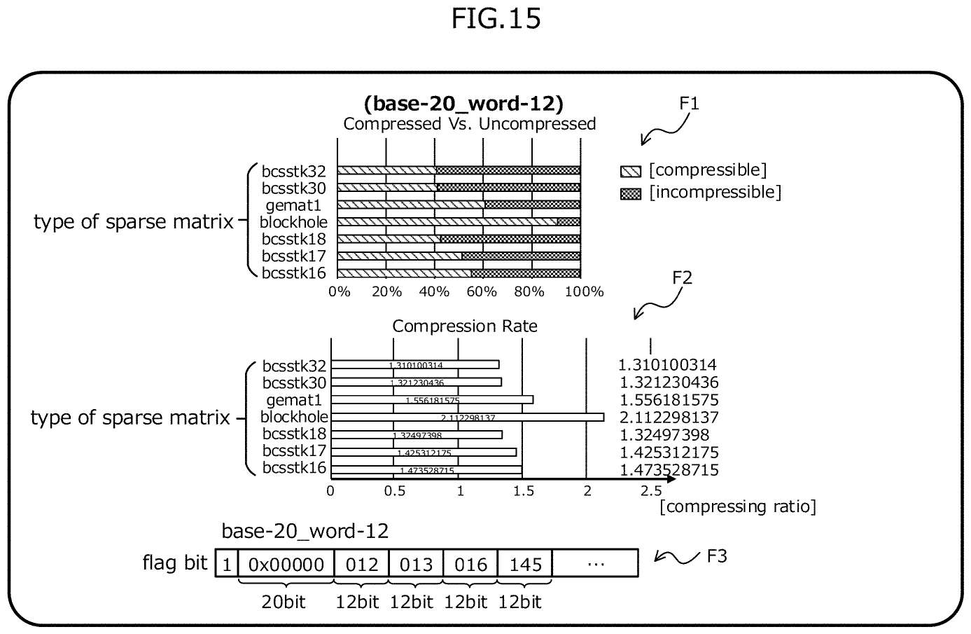

FIG. 15 is a diagram illustrating a first example of evaluating a compressing ratio in the first modification.

The example of FIG. 15 illustrates evaluation of a compressing ratio of colidx on the data of base-20_word-12.

The graph represented by the reference sign F1 indicates the compressible ratio (see oblique line pattern area) and incompressible ratio (see the lattice pattern area) for each type of sparse matrix. The graph represented by the reference sign F2 indicates a compressing ratio for each type of sparse matrix. The reference sign F3 indicates that compressed data consists of a one-bit flag bit, a 20-bit base, and multiple 12-bit words.

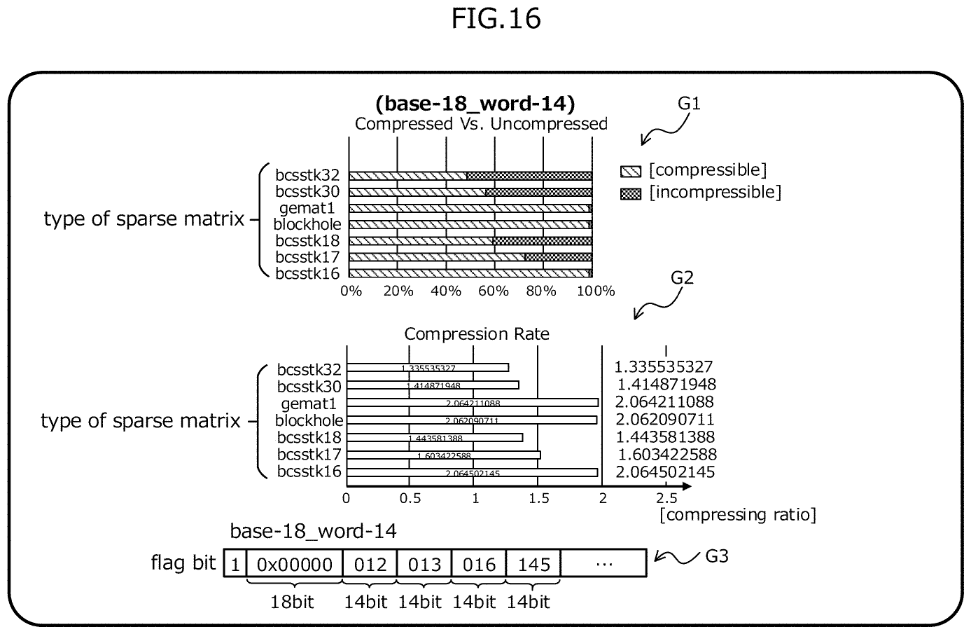

FIG. 16 is a diagram illustrating a second example of evaluating a compressing ratio in the first modification.

The example illustrated in FIG. 16 illustrates evaluation of a compressing ratio of colidx on the data of base-18_word-14.

The graph represented by the reference sign G1 indicates the compressible ratio (see oblique line pattern area) and incompressible ratio (see the lattice pattern area) for each type of sparse matrix. The graph represented by the reference sign G2 indicates a compressing ratio for each type of sparse matrix. The reference sign G3 indicates that compressed data consists of a one-bit flag bit, an 18-bit base, and multiple 14-bit words.

(B-2) Second Modification:

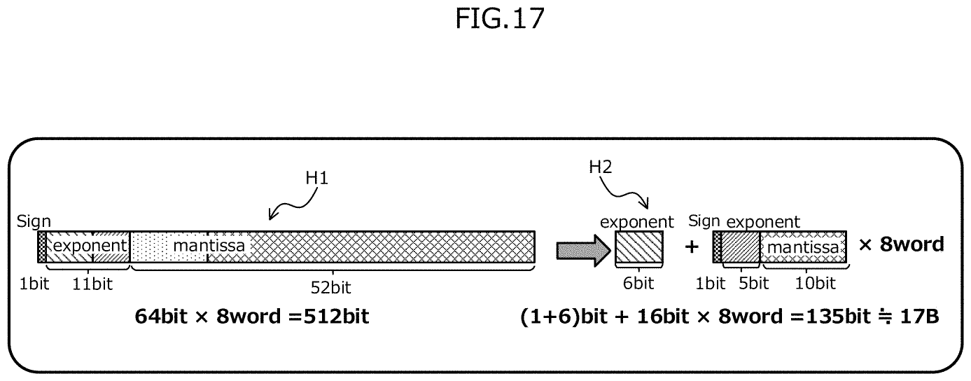

FIG. 17 is a diagram illustrating a first example of a compressing process in a second modification.

In the second modification, the exponent is expanded, and when the upper bit of the exponent is common, compression is performed in a unit of a cache line.

In the reference sign H2, data having a size of 64 bits×8 words=512 bits having a one-bit sign, an 11-bit exponent, and a 52-bit mantissa. In the reference sign H2, data having a size of (1+6) bits+16 bits x S words=135 bit≈17B, which is the sum of the data indicated by the reference sign H1 and the expanded 16-bits exponent.

That is, the transfer IF 21 divides the exponent of the floating-point data into an upper part having a predetermined bit number and a lower part. If the upper parts are common in a unit of a data block, the transfer IF 21 performs data transfer of the common upper part and the lower parts of the respective data words.

Also in the second modification, a compressing scheme may be switched on the basis of the threshold like the above-described embodiment. In addition, like the first modification described above, the second modification may perform an adjusting process of a common bit width.

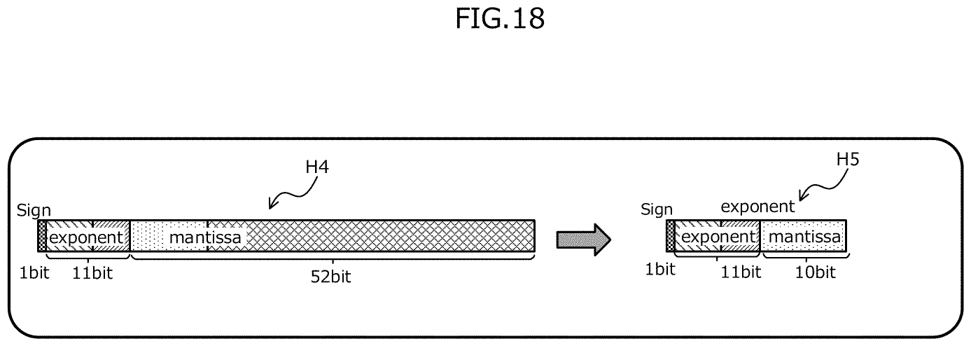

FIG. 18 is a diagram illustrating a second example of a compressing process in the second modification.

If the upper bits are not common, only mantissas may be compressed. The original data represented by the reference sign H4 consists of a one-bit sign, an 11-bit exponent, and a 52 bit mantissa. The compressed data represented by the reference sign H5 is composed of a one-bit Sign, an 11-bit exponent, and a 10-bit mantissa.

If the upper bits are not common, the mantissas may also be kept to be the double-precision. The transfer IF 21 may truncate a given lower bits in the mantissa of the floating-point data, and transfer the remainder data.

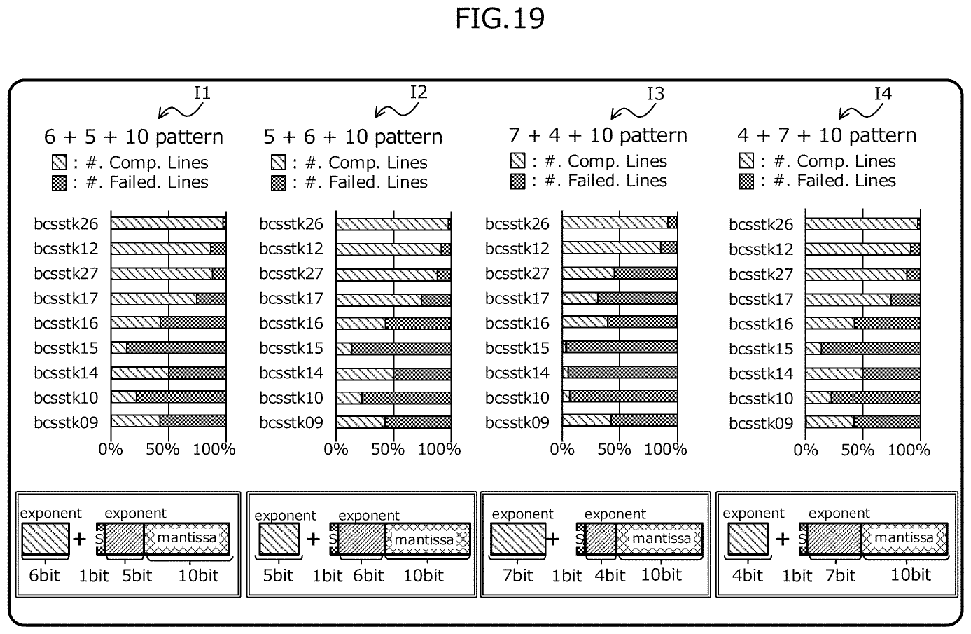

FIG. 19 is a diagram illustrating a first example of evaluating a compressing ratio in the second modification.

In relation to the data composed of a six-bit expanded exponent in addition to a five-bit exponent and a 10-bit mantissa, the reference sign I1 indicates the compressible ratio (see oblique line pattern area) and an incompressible ratio (see the lattice pattern area) for each type of sparse matrix.

In relation to the data composed of a five-bit expanded exponent in addition to a six-bit exponent and a 10-bit mantissa, the reference sign 12 indicates the compressible ratio (see oblique line pattern area) and an incompressible ratio (see the lattice pattern area) for each type of sparse matrix.

In relation to the data composed of a seven-bit expanded exponent in addition to a four-bit exponent and a 10-bit mantissa, the reference sign 13 indicates the compressible ratio (see oblique line pattern area) and an incompressible ratio (see the lattice pattern area) for each type of sparse matrix.

In relation to the data composed of a four-bit expanded exponent in addition to a seven-bit exponent and a 10-bit mantissa, the reference sign 14 indicates the compressible ratio (see oblique line pattern area) and an incompressible ratio (see the lattice pattern area) for each type of sparse matrix.

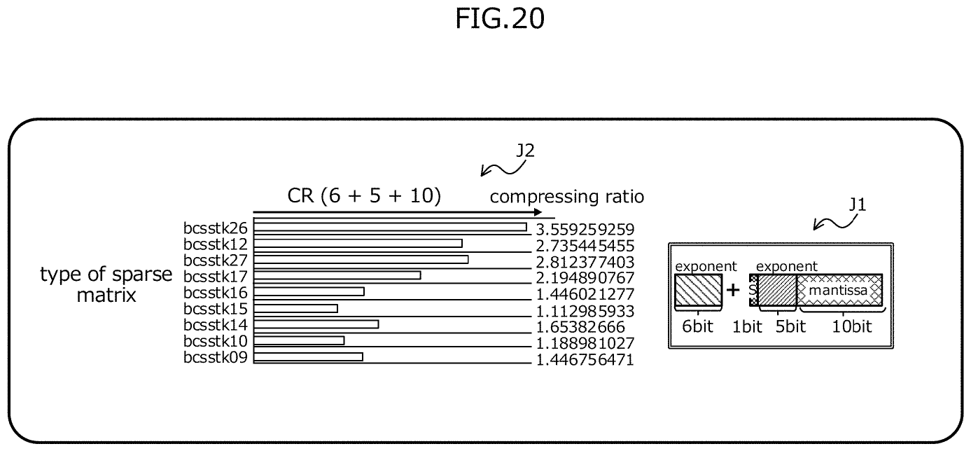

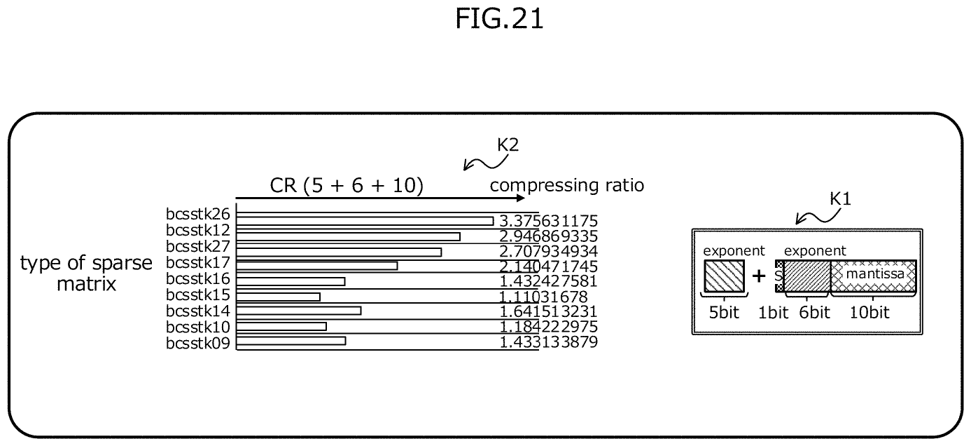

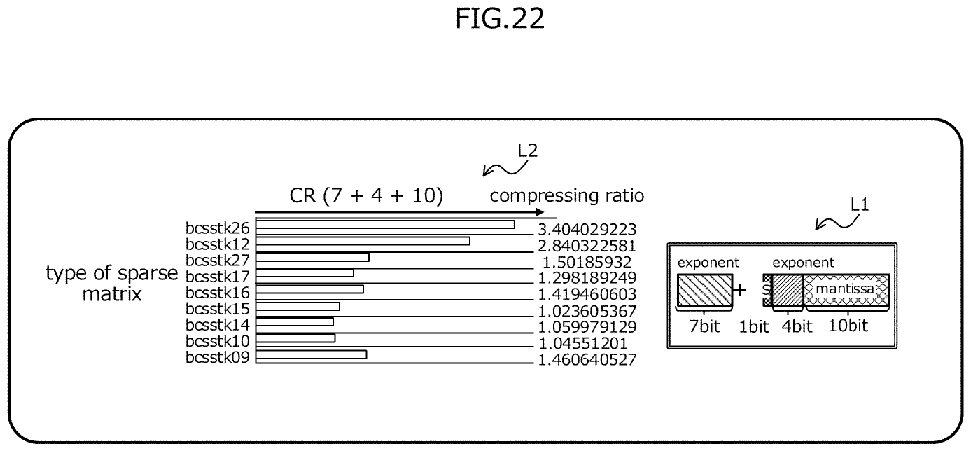

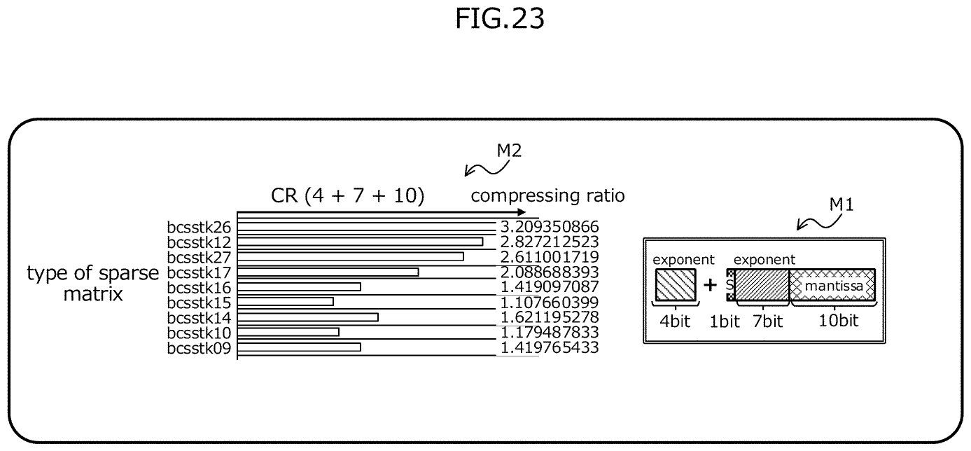

FIG. 20 is a diagram illustrating a second example of evaluating a compressing ratio in the second modification. FIG. 21 is a diagram illustrating a third example of evaluating a compressing ratio in the second modification. FIG. 22 is a diagram illustrating a fourth example of evaluating a compressing ratio in the second modification. FIG. 23 is a diagram illustrating a fifth example of evaluating a compressing ratio in the second modification.

In relation to the data (see reference sign J1) composed of a six-bits expanded exponent in addition to a five-bit exponent and a 10-bit mantissa, FIG. 20 indicates the compressible ratio (see oblique line pattern area) and incompressible ratio (see the lattice pattern area) for each type of sparse matrix (see reference sign J2).

In relation to the data (see reference sign K1) composed of a five-bits expanded exponent in addition to a six-bit exponent and a 10-bit mantissa, FIG. 21 indicates the compressible ratio (see oblique line pattern area) and incompressible ratio (see the lattice pattern area) for each type of sparse matrix (see reference sign K2).

In relation to the data (see reference sign L1) composed of a seven-bits expanded exponent in addition to a four-bit exponent and a 10-bit mantissa, FIG. 22 indicates the compressible ratio (see oblique line pattern area) and incompressible ratio (see the lattice pattern area) for each type of sparse matrix (see reference sign L2).

In relation to the data (see reference sign M1) composed of a four-bits expanded exponent in addition to a seven-bit exponent and a 10-bit mantissa, FIG. 23 indicates the compressible ratio (see oblique line pattern area) and incompressible ratio (see the lattice pattern area) for each type of sparse matrix (see reference sign M2).

(B-3) Combination of the Embodiment, the First Modification, and the Second Modification:

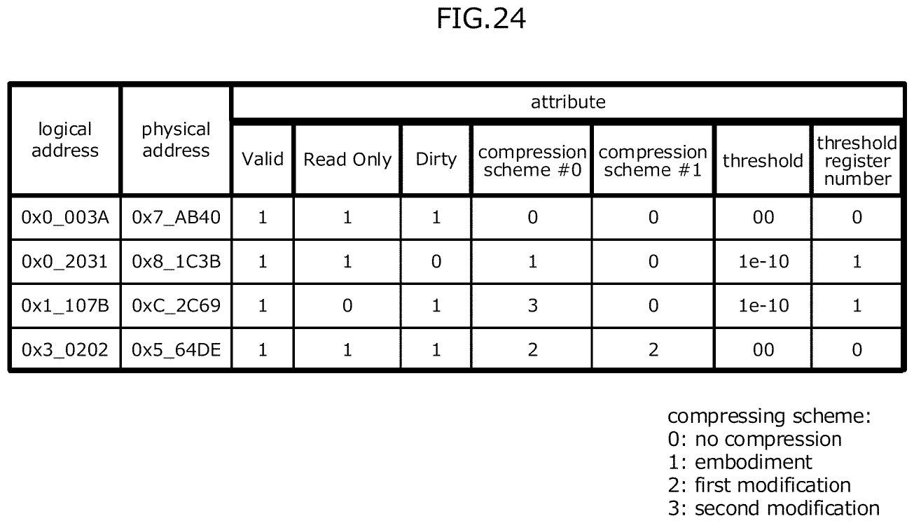

FIG. 24 is a table illustrating an example of the TLB 201 when the embodiment, the first modification, and the second modification are combined.

In the TLB 201 illustrated in FIG. 24, a logical address, a physical address, and attributes are associated with one other. The attributes may include “Valid”, “Read Only”, “Dirty”, a compressing scheme #0, a compressing scheme #1, a threshold, and a threshold register number. In the attributes of “Valid”, “Read Only” and “Dirty”, the value “1” indicates valid, and the value “0” indicates invalid. In compressing schemes #0 and #1, the value “0” indicates uncompression; the value “1” indicates compression according to the embodiment, the value “2” indicates compression according to the first modification, and the value “3” indicates compression according to the second modification.

(B-4) Example of Hardware Configuration:

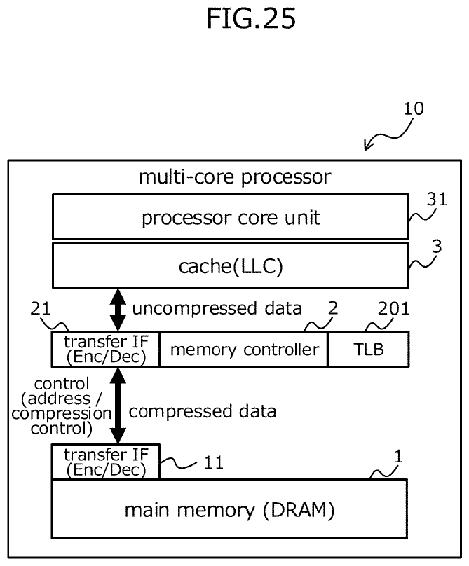

FIG. 25 is a block diagram schematically illustrating an example of the hardware configuration of the multi-core processor 10 according to the embodiment.

The multi-core processor 10 includes the main memory 1 (DRAM), the memory controller 2, the LLC 3, and a core 31 (a processor core unit). Note that DRAM is an abbreviation for Dynamic Random Access Memory.

The main memory 1 includes a transfer IF 11 and the memory controller 2 includes a transfer IF 21. Between the transfer IF 11 of the main memory 1 and the transfer IF 21 of the memory controller 2, compressed data is transmitted and received, and an address and control data for compression control is transmitted and received.

Uncompressed data is transmitted and received between the transfer IF 21 of the memory controller 2 and the LLC 3.

(B-5) Example of Operation:

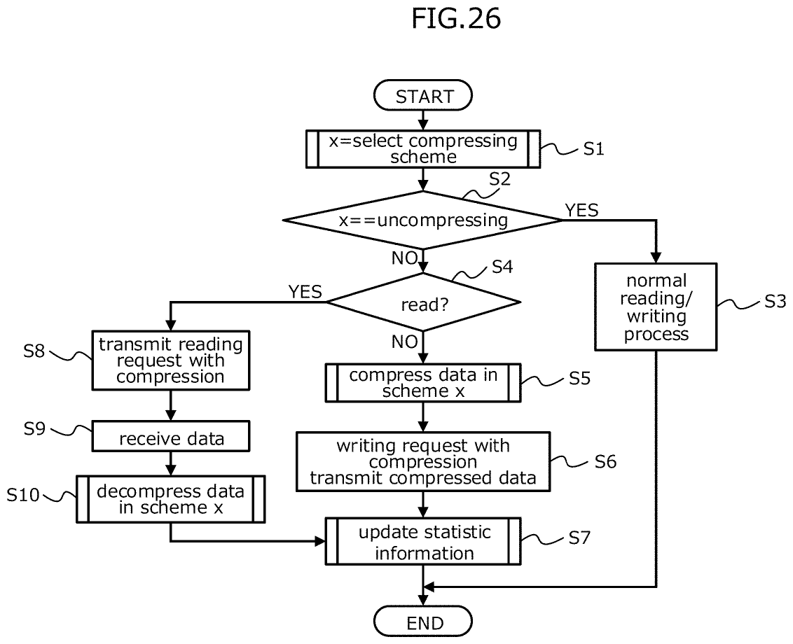

Description will now be made in relation to data transferring process in the transfer IF 21 of the memory controller 2 according to the embodiment with reference to a flow diagram (Steps S1 to S10) of FIG. 26.

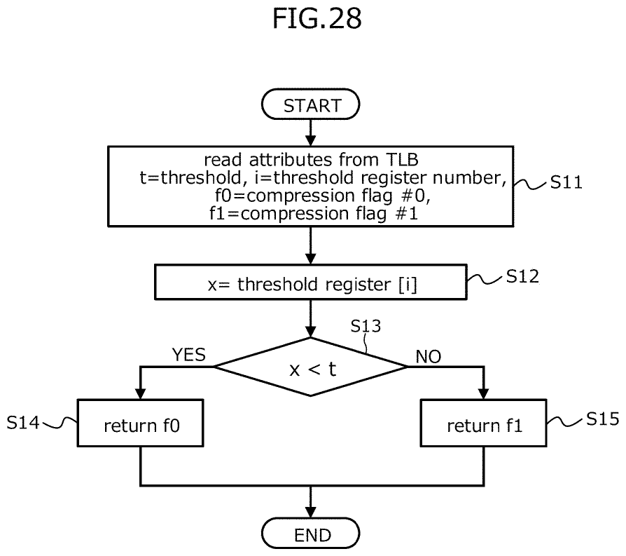

The transfer IF 21 of the memory controller 2 selects a compressing scheme x (Step S1). The details of the selecting process of a compressing scheme will be described below with reference to FIG. 28 to FIG. 30.

The transfer IF 21 determines whether the compressing scheme x is uncompressing (Step S2).

If the compressing scheme x is uncompressing (YES route of Step S2), the transfer IF 21 performs a normal reading/writing process (Step S3). Then, data transferring process in the transfer IF 21 of the memory controller 2 according to the embodiment ends.

If the compressing scheme x is not uncompressing (see NO route of Step S2), the transfer IF 21 determines whether the process is to read (Step S4).

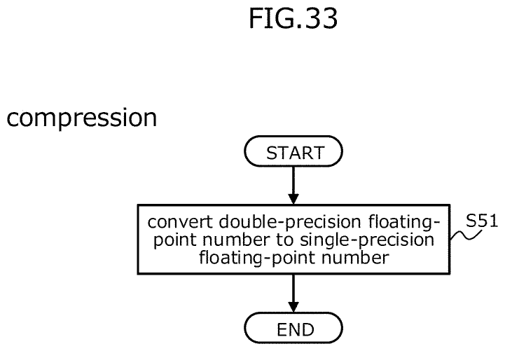

If the process is not to read (see NO route of Step S4), the transfer IF 21 performs a data compressing process in the compressing scheme x (Step S5). The details of the data compressing process will be described below with reference to FIGS. 33, 35, and 37.

The transfer IF 21 makes a writing request with compression and sends the compressed data (Step S6).

The transfer IF 21 updates the statistic information (Step S7). Then, data transferring process in the transfer IF 21 of the memory controller 2 according to the embodiment ends.

If the process is to read in Step S4 (see YES route of Step S4), the transfer IF 21 sends a reading request with compression (Step S8).

The transfer IF 21 receives data (Step S9).

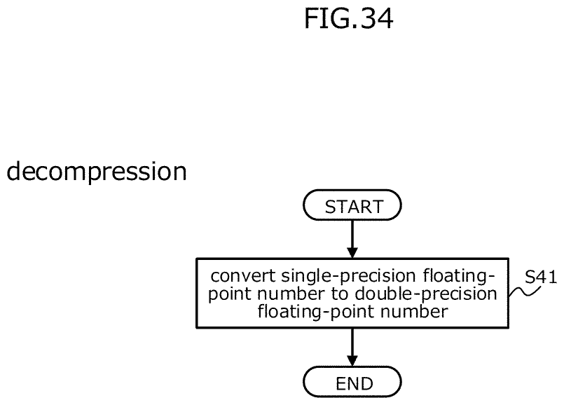

The transfer IF 21 decompresses data in the compressing scheme x (Step S10). The details of the data decompressing process will be described below with reference to FIGS. 34, 36, 38, and 40. Then, the process proceeds to Step S7.

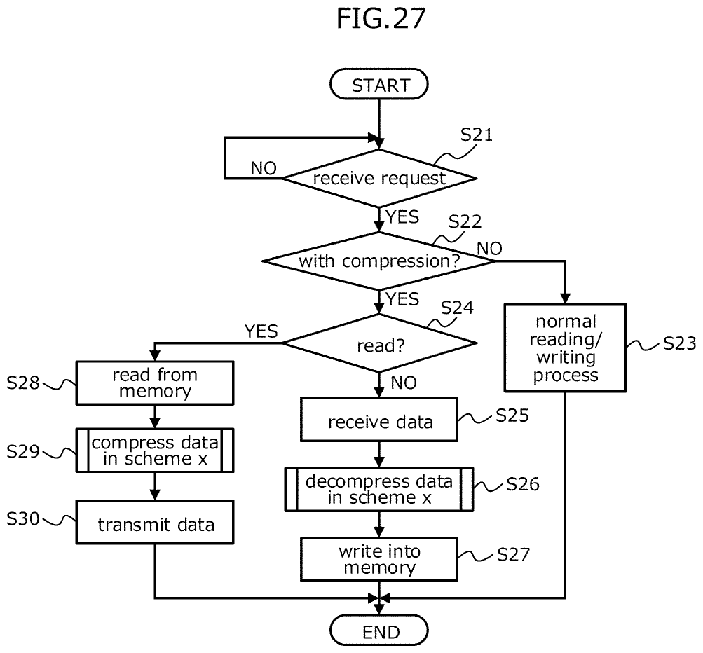

Next, description will now be made in relation to data transferring process in the transfer IF 11 of the main memory 1 according to the embodiment with reference to a flow diagram (Steps S21 to S30) of FIG. 27.

The transfer IF 11 of the main memory 1 determines whether a request for data process is received (Step S21).

If the request for data process is not received (see NO route of Step S21), the process of Step S21 is repeated.

If the request for data process is received (see YES route of Step S21), the transfer IF 11 determines whether data to be processed is data with compression (Step S22).

If the data to be processed is not data with compression (see NO route of Step S22), the transfer IF 11 performs a normal reading/writing process (Step S23). Then, the data transferring process in the transfer IF 11 of the main memory 1 according to the embodiment ends.

On the other hand, if the data to be processed is data with compression (see YES route of Step S22), the transfer IF 11 determines whether the process is to read (Step S24).

If the process is not to read (see NO route of Step S24), the transfer IF 11 receives data (Step S25).

The transfer IF 11 decompresses the data in the compressing scheme x (Step S26). The details of the data decompressing process will be described below with reference to FIGS. 34, 36, 38, and 40.

The transfer IF 11 writes data into the main memory 1 (Step S27), and then the data transferring process in the transfer IF 11 of the main memory 1 according to the embodiment ends.

If the process is to read in Step S24 (see YES route of Step S24), the transfer IF 11 reads the data from the main memory 1 (Step S28).

The transfer IF 11 performs a data compressing process in the compressing scheme x (Step S29). The details of the data compressing process will be described below with reference to FIGS. 33, 35, and 37.

The transfer IF 11 transmits the data (Step S30), and then the data transferring process in the transfer IF 11 of the main memory 1 according to the embodiment ends.

Next, the selecting process of the compressing scheme according to the embodiment will now be described with reference to a flow diagram (Steps S11 to S15) illustrated in FIG. 28.

The transfer IF 21 of the memory controller 2 reads attributes from the TLB 201 (Step S11). The attributes to be read may be, for example, t=threshold, i=threshold register number, and f0=compression flag #0, and f1=compression flag 1.

The transfer IF 21 sets the value “i” of the threshold register 22 in the variable x (Step S12).

The transfer IF 21 determines whether a relationship x<t is satisfied (Step S13).

If the relationship x<t is satisfied (see YES route of Step S13), the transfer IF 21 returns an f0 (Step S14). Then, the selecting process of the compressing scheme according to the embodiment ends.

On the other hand, if a relationship x≥t is satisfied (see NO route of Step S13), the transfer IF 21 returns f1 (Step S15). Then, the selecting process of the compressing scheme according to the embodiment ends.

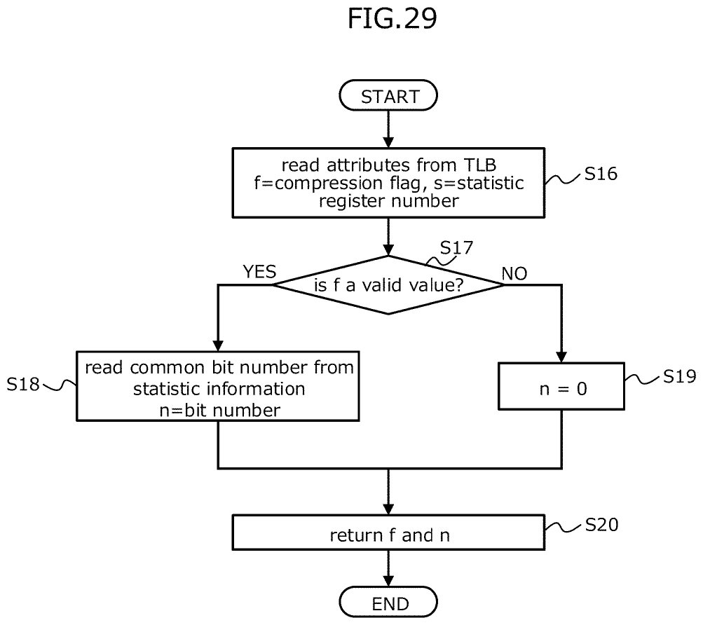

Next, description will now be made in relation to a selecting process of the compressing scheme according to the first modification and the second modification with reference to the flow diagram (Steps S16 to S20) of FIG. 29.

The transfer IF 21 of the memory controller 2 reads an attribute from the TLB 201 (Step S16). The attributes to be read may be, for example, f=compression flag and s=statistic register number.

The transfer IF 21 determines whether f is a valid value (Step S17).

If f is a valid value (see YES route of Step S17), the transfer IF 21 reads the common bit from the statistic information and sets n=bit number (Step S18). Then, the process proceeds to Step S20.

On the other hand, if f is not a valid value (see NO route in Step S17), the transfer IF 21 sets n=0 (Step S19).

The transfer IF 21 returns the f and n (Step S20). Then, the selecting process of the compressing scheme according to the first modification, and the second modification ends.

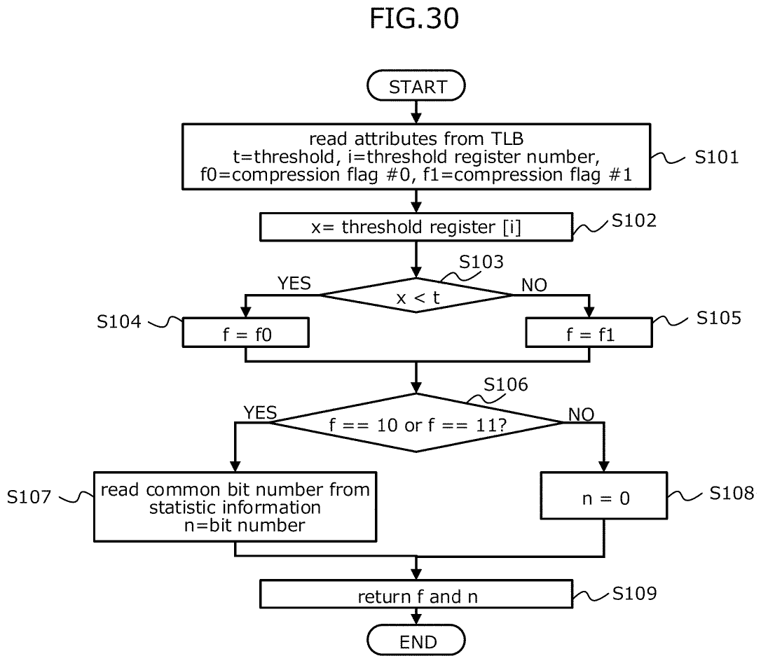

Next, description will now be made in relation to a selecting process of a compressing scheme according to the embodiment, the first modification, and the second modification with reference to a flow diagram (Steps S101 to S109) of FIG. 30.

The transfer IF 21 of the memory controller 2 reads the attributes from the TLB 201 (Step S101). The attributes to be read may be, for example, t=threshold, i=threshold register number, and f0=compression flag #0, and f1=compression flag #1.

The transfer IF 21 sets the value “i” of the threshold register 22 in the variable x (Step S102).

The transfer IF 21 determines whether a relationship x<t is satisfied (Step S103).

If the relationship x<t is satisfied (see YES route of Step S103), the transfer IF 21 returns a f=f0 (Step S104). Then, the process proceeds to Step S106.

On the other hand, if a relationship x≥t is satisfied (see NO route of Step S103), the transfer IF 21 returns f=f1 (Step S105).

The transfer IF 21 determines whether f==10 or f==f1 (Step S106).

If f==10 or f==11 (see YES route in Step S106), the transfer IF 21 reads the common bits from the statistic information and sets n=bit number (Step S107). Then, the process proceeds to Step S109.

On the other hand, if neither f==10 nor f==11 is satisfied (see NO route in Step S106), the transfer IF 21 sets n=0 (Step S108).

The transfer IF 21 returns f and n (Step S109). Then, the selecting process of the compressing scheme according to the embodiment, the first modification, and the second modification ends.

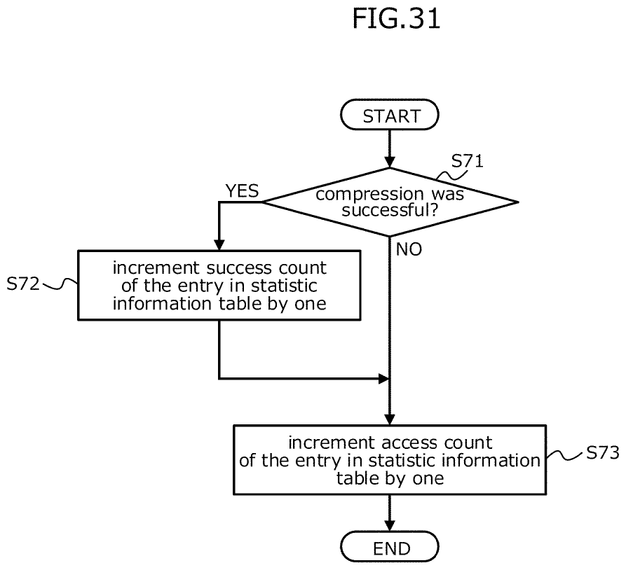

Next, description will now be made in relation to an updating process of the statistic information when data transmitting and receiving according to the embodiment with reference to a flow diagram (Steps S71 to S73) of FIG. 31.

The transfer IF 21 of the memory controller 2 determines whether the compression was successful (Step S71).

If the compression was not successful (see NO route of Step S71), the process proceeds to Step S73.

On the other hand, if the compression was successful (see YES route in Step S71), the transfer IF 21 increments the success count of the entry in the statistic information table by one (+1) (Step S72).

The transfer IF 21 increments the access count in the statistic information table by one (+1) (Step S73). Then, the updating process of the statistic information when data transmitting and receiving according to the embodiment ends.

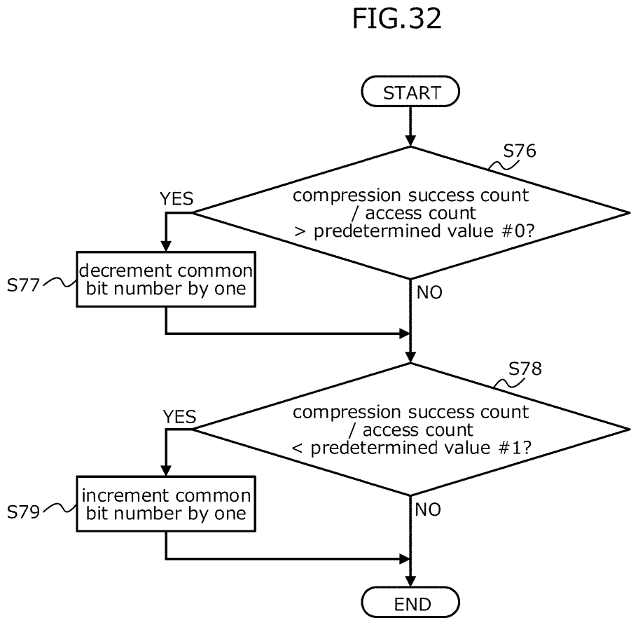

Next, description will now be made in relation to an updating process of the statistic information when bit width adjustment in the embodiment with reference to a flow chart (Steps S76 to S79) of FIG. 32.

The transmission IF 21 of the memory controller 2 determines whether or not a relationship (compression success count)/(access count)>predetermined value #0 is satisfied (Step S76).

If a relationship (compression success count)/(access count)≤predetermined value #0 is satisfied (see NO route in Step S76), the process proceeds to Step S78.

On the other hand, if a relationship (compression success count)/(access count)>predetermined value #0 is satisfied (see YES route of Step S76), the transfer IF 21 decrement the common bit number by one (−1) (Step S77).

The transmission IF 21 of the memory controller 2 determines whether or not a relationship (compression success count)/(access count)<predetermined value #1 is satisfied (Step S78).

If the relationship (compression success count)/(access count)≥predetermined value #1 (see NO route of Step S78), the updating process of the statistic information when bit width adjustment in the embodiment ends.

If the relationship (compression success count)/(access count)<predetermined value #1 (see YES route in Step S78), the transfer IF 21 increments the common bit number by one (Step S79). Then, the updating process of the statistic information when bit width adjustment in the embodiment ends.

Next, description will now be made in relation to a data compressing process according to the embodiment with reference to a flow diagram (Step S51) illustrated in FIG. 33.

The transfer IF 11 converts a double-precision floating-point number to a single-precision floating-point number (Step S51), and the data compressing process of the embodiment ends.

Next, description will now be made in relation to a data decompressing process according to the embodiment with reference to a flow diagram (Step S41) of FIG. 34.

The transfer IF 11 converts a single-precision floating-point number to a double-precision floating-point number (Step S41), and the data decompressing process of the embodiment ends.

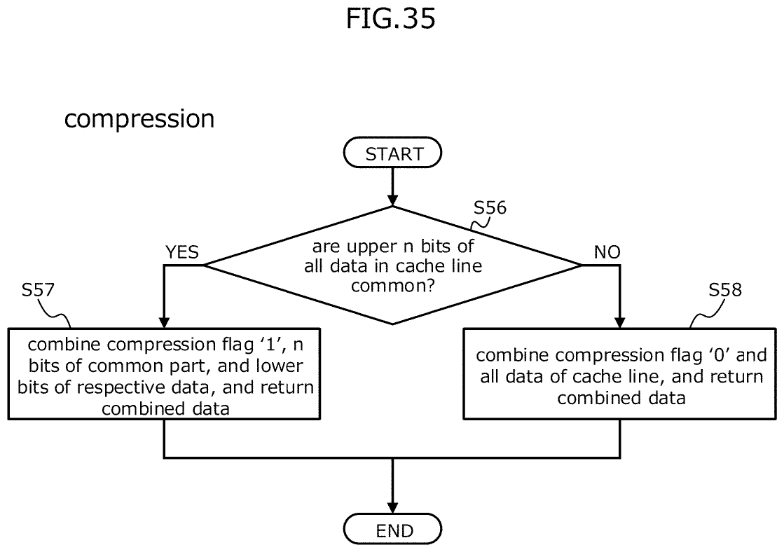

Next, description will now be made in relation to a data compressing process of the first modification with reference to a flow diagram (Steps S56 to S58) of FIG. 35.

The transfer IF 11 determines whether the upper n bits of all data in the cache line are common (Step S56).

If the upper n bits of all data in the cache line are common (see YES route of Step S56), the transfer IF 11 combines the compression flag ‘1’, the n bits of the common part, and the lower bits of the respective data, and returns the combined data (Step S57). Then, the data compressing process of the first modification ends.

On the other hand, if the upper n bits of all data in the cache line are not common (see NO route of Step S56), the transfer IF 11 combines the compression flag ‘0’ and all data of the cache line and returns the combined data (Step S58). Then, the data compressing process of the first modification ends.

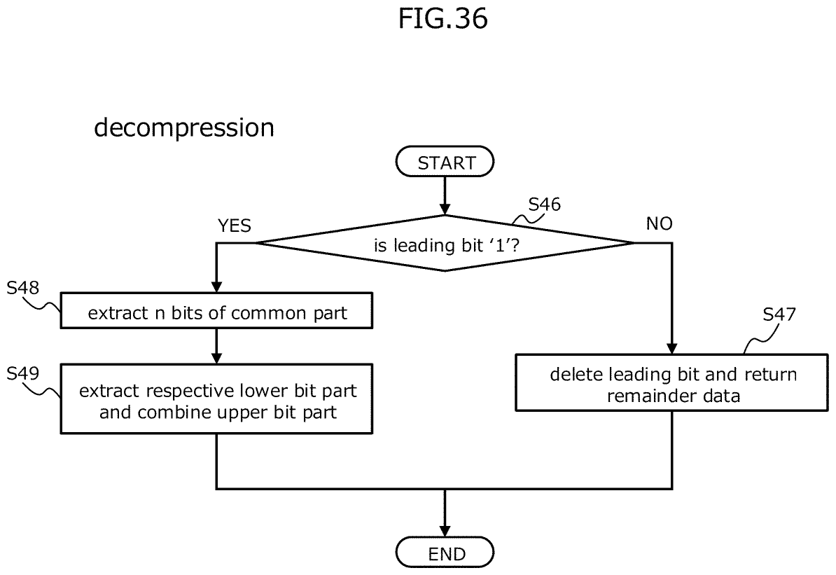

Next, description will now be made in relation to a data decompressing process of the first modification with reference to a flow diagram (Steps S46 to S49) of FIG. 36.

The transfer IF 21 determines whether the leading bit is “1” (Step S46).

If the leading bit is not ‘1’ (see NO route of Step S46), the transfer IF 21 deletes the leading bit and returns the remainder data (Step S47). Then, the data decompressing process of the first modification ends.

On the other hand, if the leading bit is ‘1’ (see YES route of Step S46), the transfer IF 21 extracts the n bits of the common part (Step S48).

The transfer IF 21 extracts the respective lower bit parts and combines the upper bit parts (Step S49). Then, the data decompressing process of the first modification ends.

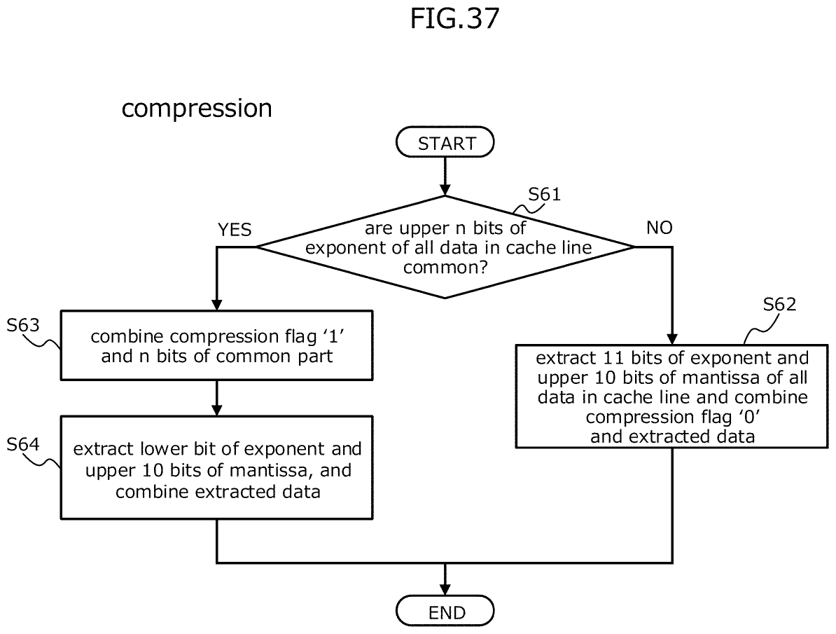

Next, description will now be made in relation to a first example of a data compressing process of the second modification with reference to a flow diagram (Steps S61 to S64) of FIG. 37.

The transfer IF 21 determines whether the upper n bits of the exponents of all data in the cache line are common (Step S61).

If the upper n bits of the exponents of all data in the cache line are not common (see NO route of Step S61), the transfer IF 21 extracts the 11 bits of the exponent and the upper 10 bits of the mantissa for all data of the cache line and combines the compression flag ‘0’ and the extracted data (Step S62). Then, the first example of the data compressing process of the second modification ends.

On the other hand, if the upper n bits of the exponents of all data in the cache line are common (see YES route of Step S61), the transfer IF 21 combines the compression flag ‘1’ and the n bits of the common part (Step S63).

The transfer IF 21 extracts the lower bits of the exponent of each data, extracts upper 10 bits of the mantissa, and combines the extracted data (Step S64). Then, the first example of the data compressing process of the second modification ends.

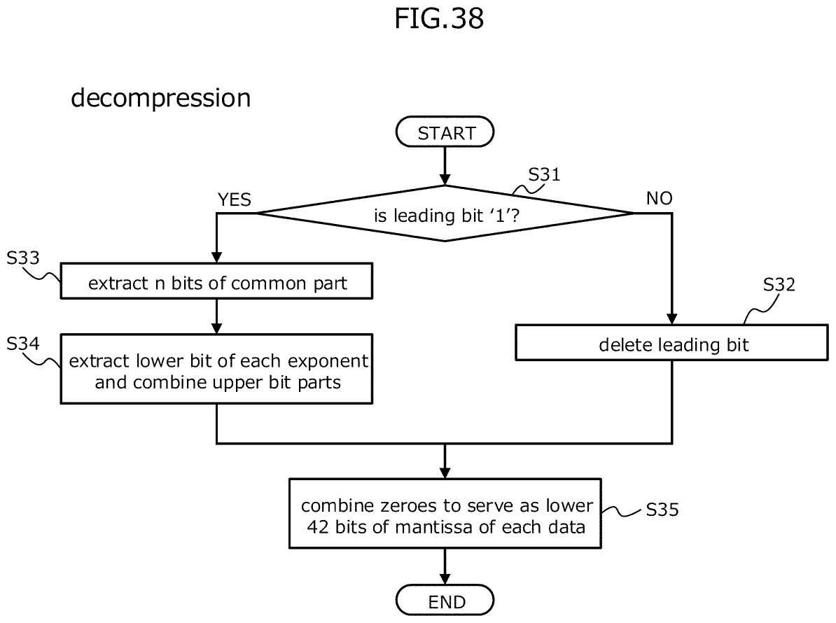

Next, description will now be made in relation to a first example of a data decompressing process of the second modification with reference to a flow diagram (Steps S31 to S35) of FIG. 38.

The transfer IF 21 determines whether the leading bit is “1” (Step S31).

If the leading bit is not “1” (see NO route of Step S31), the transfer IF 21 deletes the leading bit (Step S32). Then, the process proceeds to Step S35.

On the other hand, if the leading bit is “1” (see YES route of Step S31), the transfer IF 21 extracts the n bits of the common part (Step S33).

The transfer IF 21 extracts the lower bit part of each exponent and combines the upper bit parts (Step S34).

The transfer IF 21 combines zeros to server as the lower 42 bits of the mantissa of each data (Step S35). Then, the first example of data decompression process as the first modification ends.

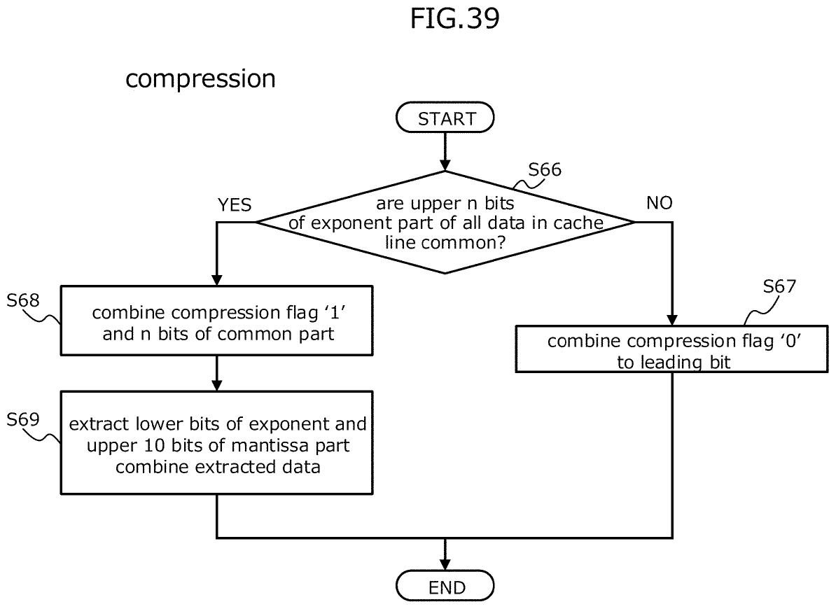

Next, description will now be made in relation to a second example of a data compressing process of the second modification with reference to a flow diagram (Steps S66 to S69) of FIG. 39.

the transfer IF 21 determines whether the upper n bits of the exponents of all data in the cache line are common (Step S66).

If the upper n bits of the exponents of all data in the cache line are not common (see NO route of Step S66), the transfer IF 21 is combines the compression flag ‘0’ to the leading bit (Step S67). Then, the second example of the compressing process of the second modification ends.

On the other hand, if the upper n bits of the exponents of all data in the cache line are common (see YES route of Step S66), the transfer IF 21 combines the compression flag ‘1’ and the n bits of the common part (Step S68).

The transfer IF 21 extracts the lower bits of the exponent of each data, extracts upper 10 bits of the mantissa, and combines the extracted data (Step S69). Then, the second example of the compressing process of the second modification ends.

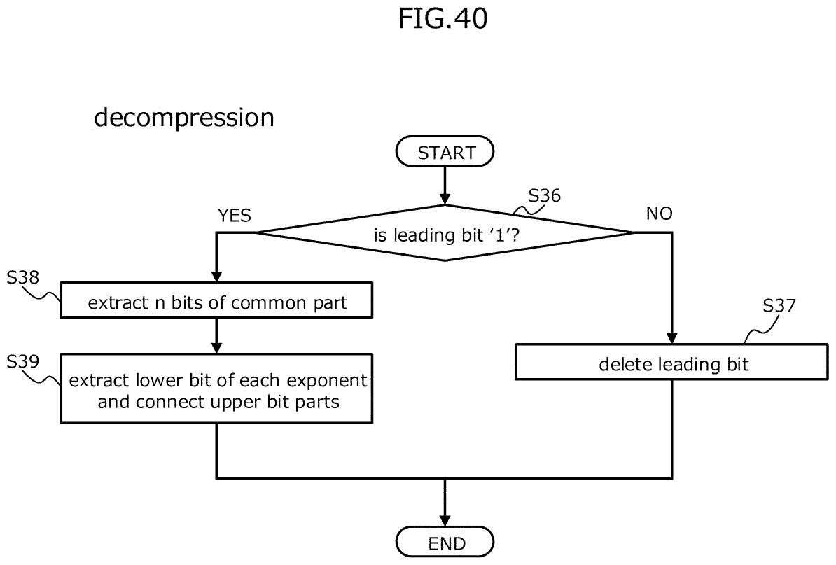

Next, description will now be made in relation to a second example of a data decompressing process of the second modification with reference to a flow diagram (Steps S36 to S39) of FIG. 40.

The transfer IFs 11 and 21 determine whether the leading bit is “1” (Step S36).

If the leading bit is not “1” (see NO route of Step S36), the transfer IF 21 deletes the leading bit (Step S37). Then, the second example of data decompressing process as the second modification ends.

On the other hand, if the leading bit is ‘1’ (see YES route of Step S36), the transfer IF 21 extracts the n bits of the common part (Step S38).

The transfer IF 21 extracts the lower bit part of each exponent and combines the upper bit parts (Step S39). Then, the second example of data decompression process as the second modification example ends.

### (C) Effect

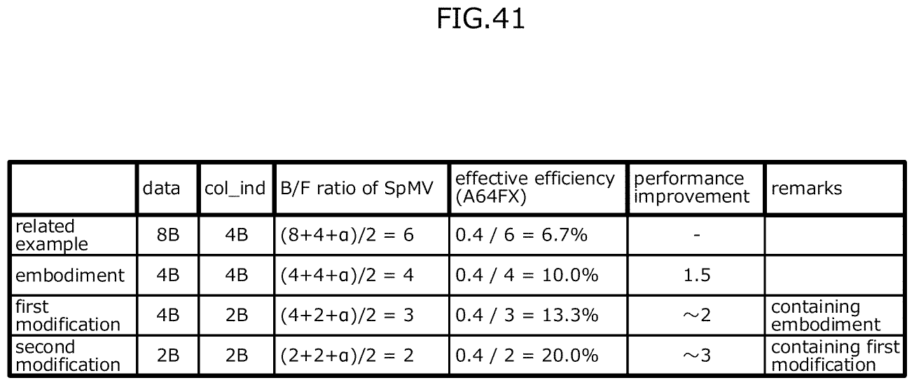

FIG. 41 is a table illustrating performance of SpMV calculation by data compression of the embodiment, and the first modification, and the second modification.

The data of the related example, the embodiment, the first modification, and the second modification have data sizes of 8 B, 4 B, 4 B, and 2 B, respectively. The col_ind of the related example, the embodiment, the first modification, and the second modification have data sizes of 4 B, 4 B, 2 B, and 2 B, respectively. The SpMVs in the related example, the embodiment, the first modification, and the second modification have the B/F ratios of 6, 4, 3, and 2, respectively. The execution efficiencies in the related example, the embodiment, the first modification, and the second modification are 6.7%, 10.0%, 13.3%, and 20.0%, respectively. The performance improvement rates of the embodiment, the first modification example, and the second modification to the related example are 1.5 times, 2 times at maximum, 3 times at maximum, respectively.

The arithmetic processing apparatus and the method for memory access the above embodiment can bring the following effects.

In the data transfer between the main memory 1 and the memory controller 2, the transfer IF 21 refers to the attribute of the compressing scheme for data on main memory 1, and performs data transfer by switching the compressing scheme based on the referred attribute. This makes it possible to accelerate the memory accessing.

The transfer IF 21 switches the compressing scheme on the basis of the result of comparison of the predetermined threshold with the value of the threshold register 22 provided in the memory controller 2. This makes it possible to efficiently switch the compressing scheme.

The transfer IF 21 divides each of the cache lines of data into an upper part having a predetermined bit number and a lower part. When the upper parts of the respective cache line are common, the transfer IF 21 combines the common upper part and the lower parts of the respective data words, and executes the data transfer on the combined data. This makes it possible to efficiently compress the data to be transferred.

The transfer IF 21 divides the exponent of the floating-point data into an upper part having a predetermined bit number and a lower part. When the upper parts of the respective cache line are common, the transfer IF 21 combines the common upper part and the lower parts in a unit of a data block, and executes the data transfer on the combined data. This can efficiently compress floating-point data to be transferred.

The transfer IF 21 changes the bit number of the upper part according to the success ratio of data compressing. This makes it possible to efficiently compress the data to be transferred.

The transfer IF 21 truncates a given lower bits in the mantissa of the floating-point data, and transfers the remaining data. This makes it possible to accelerate the memory accessing.

### (D) Miscellaneous

The disclosed techniques are not limited to the embodiment described above, and may be variously modified without departing from the scope of the present embodiment. The respective configurations and processes of the present embodiment can be selected, omitted, and combined according to the requirement.

In one aspect, memory access can be accelerated.

In the claims, the indefinite article “a” or “an” does not exclude a plurality.

All examples and conditional language recited herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. An arithmetic processing apparatus comprising
a controlling unit that refers to an attribute of a compressing scheme on data on a main memory when the data is transferred between the main memory and a memory controller, and that transfers the data by switching the compressing scheme based on the referred attribute.

2. The arithmetic processing apparatus according to claim 1, wherein
the attribute is a given threshold, and
the controlling unit switches, based on a comparison result between the given threshold and a value of a threshold register provided to the memory controller, the compressing scheme.

3. The arithmetic processing apparatus according to claim 1, wherein
the controlling unit divides each of a plurality of cache lines of the data into an upper part having a given bit number and a lower part, and
when the upper parts of each of data in a cache line are common, the controlling unit combines the common upper part and the lower parts of respective data words and transfers the combined data as the data.

4. The arithmetic processing apparatus according to claim 1, wherein
the data is floating-point data,
the controlling unit divides an exponent of the floating-point data into an upper part having a given bit number and a lower part, and
when the upper parts of each of data in a data block are the common, the controlling unit combines the common upper part and the lower parts of respective data words and transfers the combined data as the data.

5. The arithmetic processing apparatus according to claim 3, wherein the controlling unit changes the given bit number of the upper bit in accordance with a success ratio of compressing the data.

6. The arithmetic processing apparatus according to claim 4, wherein the controlling unit changes the given bit number of the upper bit in accordance with a success ratio of compressing the data.

7. The arithmetic processing apparatus according to claim 1, wherein
the data is floating-point data,
the controlling unit truncates given lower bits in an mantissa of the floating-point data and transfers remainder data as the data.

8. A method for memory access comprising:
referring to an attribute of a compressing scheme on data on a main memory when the data is transferred between the main memory and a memory controller; and
transferring the data by switching the compressing scheme based on the referred attribute.

9. The method according to claim 8, wherein
the attribute is a given threshold, and
the method further comprises switching, based on a comparison result between the given threshold and a value of a threshold register provided to the memory controller, the compressing scheme.

10. The method according to claim 8, further comprising:
dividing each of a plurality of cache lines of the data into an upper part having a given bit number and a lower part, and
when the upper parts of each of data in a cache line are common, combining the common upper part and the lower parts of respective data words and transfers the combined data as the data.

11. The method according to claim 8, wherein
the data is floating-point data,
the method further comprises
dividing an exponent of the floating-point data into an upper part having a given bit number and a lower part, and
when the upper parts of each of data in a data block are the common, combining the common upper part and the lower parts of respective data words and transfers the combined data as the data.

12. The method according to claim 10, further comprising changing the given bit number of the upper bit in accordance with a success ratio of compressing the data.

13. The method according to claim 11, further comprising changing the given bit number of the upper bit in accordance with a success ratio of compressing the data.

14. The method according to claim 8, wherein
the data is floating-point data,
the method further comprises truncating given lower bits in an mantissa of the floating-point data and transfers remainder data as the data.
